(19) United States
(12) Patent Application Publication
(10) Pub. No.: US 2007/0164389 A1
(43) Pub. Date: Jul. 19, 2007

(54) CMOS IMAGE SENSOR

(76) Inventor: Tae Young Lee, Gyeonggi-do (KR)

Correspondence Address: SHERR & NOURSE, PLLC, 620 HERNDON PARKWAY, SUITE 200, HERNDON, VA, 20170, US

(21) Appl. No.: 11/613,106

(22) Filed: Dec. 19, 2006

(30) Foreign Application Priority Data
Dec. 29, 2005 (KR) 10-2005-0134451

(51) Int. Cl. H01L 21/00; H01L 31/0232; H01L 31/06

(52) U.S. Cl. 257/461; 257/432; 438/65

(57) ABSTRACT

Embodiments relate to an image sensor that may use a passivation layer and a method for manufacturing the same. In embodiments, an image sensor may include a semiconductor substrate on which a photodiode and a transistor for the image sensor are formed, and a passivation layer formed over an entire surface of the semiconductor substrate. The passivation layer may include a first insulation layer made of TEOS, and a second insulation layer made of a nitride material formed on the first insulation layer.

The present application claims priority under 35 U.S.C. 119 and 35 U.S.C. 365 to Korean Patent Application No. 10-2005-0134451 (filed on Dec. 29, 2005), which is hereby incorporated by reference in its entirety.

### BACKGROUND

Image sensors may be semiconductor devices that may transform an optical image to electrical signals. The image sensor may generally classified into a charge coupled device (CCD) and a CMOS image sensor.

It may be beneficial to improve a photosensitivity of image sensors. Light collection technology may be important to improving photosensitivity.

A CMOS image sensor may be composed of a photo sensing circuit for sensing light and a CMOS logic circuit for processing the sensed light into electric signals. For better photosensitivity, light may be collected in a photodiode (i.e. a photo sensing device) by changing a path of light incident to regions other than the photo sensing circuit.

Such an image sensor may include a semiconductor substrate, a passivation layer, a color filter layer, and a plurality of microlenses. A photodiode may be formed on the semiconductor substrate. The passivation layer may protect devices formed on the semiconductor substrate. The color filter layer may be formed on the passivation layer. The plurality of microlenses may be formed on the color filter layer.

The passivation layer may include a first insulating layer and a second insulating layer. The first insulating layer may be made of a silicon oxide layer, and the second insulating layer may be made of nitride materials, and may be formed on the first insulating layer.

Because the second insulating layer of nitride material may be relatively weak, it may crack due to an external shock.

FIG. 1 is an image illustrating a surface of an insulating layer having nitride materials according to the related art.

Referring to FIG. 1, when second insulating layer receives an external shock, a surface of the second insulating layer may be easily cracked.

If a crack occurs in a surface of the second insulating layer, a stress applied to the second insulating layer may be increased in a subsequent process. This may cause a peeling phenomenon to occur. The peeling phenomenon may cause a surface of the second insulating layer to peel. When the peeling phenomenon occurs, external pollutants may pass through the second insulating layer and may easily enter in an internal device. Accordingly, a reliability of the device may be deteriorated.

### SUMMARY

Embodiments relate to an image sensor. Embodiments relate to an image sensor using a passivation layer that may be capable of preventing crack and a method for manufacturing the same.

Embodiments relate to an image sensor that may use a passivation layer capable of minimizing the damage of a second insulating layer by using TEOS (instead of a silicon oxide layer) as a first insulating layer and a method for manufacturing the same.

According to embodiments, an image sensor may include a semiconductor substrate on which a photodiode and a transistor for the image sensor may be formed, and a passivation layer formed on a surface (for example, the entire surface) of the semiconductor substrate, wherein the passivation layer may include a first insulation layer made of TEOS, and a second insulation layer made of a nitride material and formed on the first insulation layer.

According to embodiments, an image sensor may include a substrate on which a plurality of photodiodes and transistors may be formed, and a passivation layer formed on a surface (for example, the entire surface) of the semiconductor substrate in order to protect the photodiodes and transistors of the substrate, a color filter layer formed on the passivation layer, a plurality of microlenses formed on the color filter layer, wherein the passivation layer may include a first insulation layer made of TEOS, and a second insulation layer made of a nitride material and formed on the first insulation layer.

In embodiments, the image sensor may further include an interlayer dielectric formed between the substrate and the passivation layer, and made of at least one layer.

In embodiments, the image sensor may further include a plurality of light shield layers in the interlayer dielectric so as to prevent light from being irradiated to a remaining part except for a formation region of the photodiodes of the substrate.

In embodiments, the image sensor may further include a planarization layer formed between the color filter layer and the microlenses for planarizing the color filter layer.

According to embodiments, a method for manufacturing an image sensor, may include forming a plurality of transistors and photodiodes on a substrate, forming a first insulating layer of TEOS on a surface (for example, the entire surface) of the substrate including the plurality of transistors and photodiodes, forming a second insulating layer of nitride material formed on the first insulating layer, forming a color filter layer on the second insulating layer, and forming a plurality of microlenses on the color filter layer.

In embodiments, the method may further include an interlayer dielectric formed between the substrate and the first insulating layer, and made of at least one layer.

In embodiments, the method may further include forming a plurality of light shield layers in the interlayer dielectric.

In embodiments, the method may further include forming a planarization layer between the color filter layer and the microlenses.

The second insulating layer may be formed by one of an HDP CVD method and a PECV method.

### BRIEF DESCRIPTION OF THE DRAWINGS

FIG. 1 is an image illustrating a surface of an insulating layer having nitride materials according to the related art;

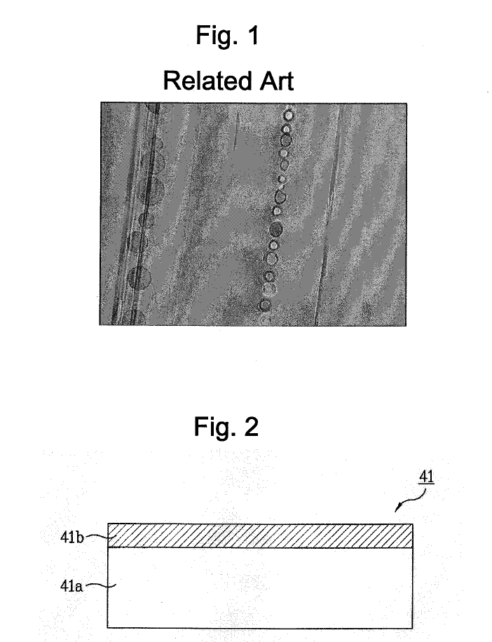

FIG. 2 is an example cross-sectional diagram illustrating a passivation layer of a semiconductor device according to embodiments;

FIG. 3 is an image illustrating a surface of a second insulating layer of FIG. 2 according to embodiments;

FIG. 4 is an example cross-sectional diagram illustrating an image sensor according to embodiments; and

FIGS. 5A through 5F are example cross-sectional diagrams of an image sensor illustrating a method for manufacturing an image sensor according to embodiments.

### DETAILED DESCRIPTION OF EMBODIMENTS

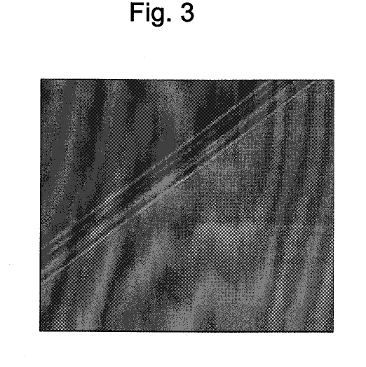

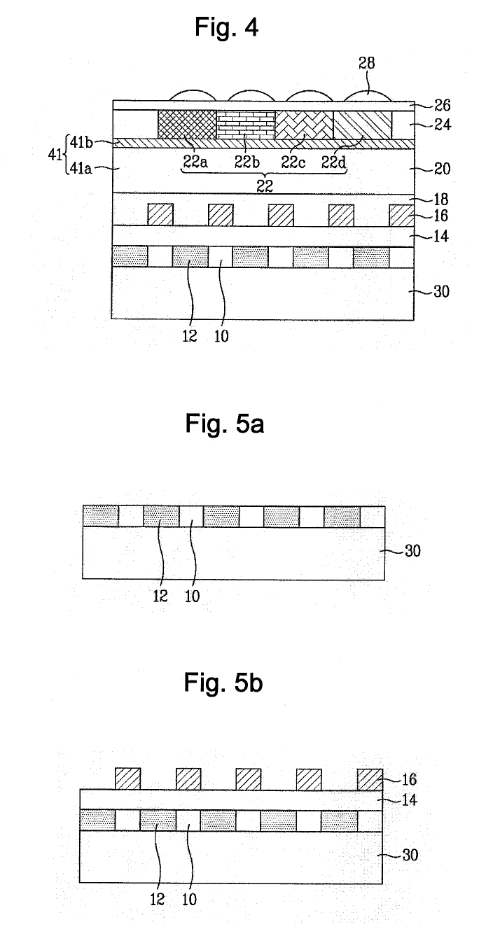

FIG. 2 is an example cross-sectional diagram illustrating a passivation layer of a semiconductor device according to embodiments. FIG. 3 is an image illustrating a surface of second insulating layer of FIG. 2, according to embodiments.

Referring to FIG. 2, passivation layer 41 of a semiconductor device according to embodiments may include a first insulating layer 41a, for example formed of TEOS material, and second insulating layer 41b, for example formed of nitride material and formed on first insulating layer 41a.

In embodiments, second insulating layer 41a may be deposited by one of an HDP CVD method and a PECV method. If second insulating layer 41b is deposited on first insulating layer 41a, as shown in FIG. 3, a peeling phenomenon may be prevented in a surface of second insulating layer 41b.

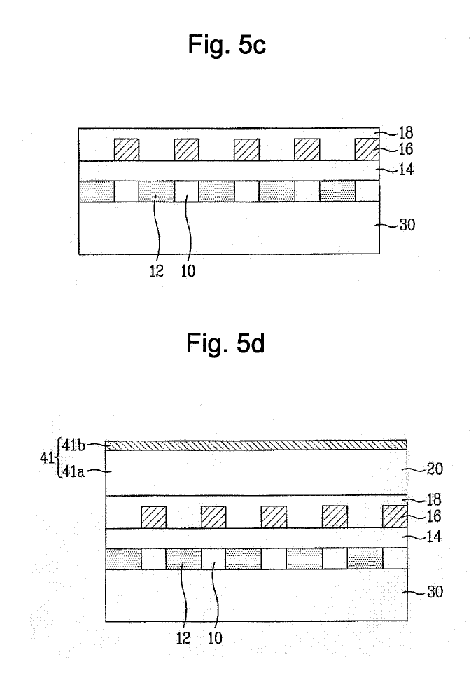

FIG. 4 is an example cross-sectional diagram illustrating an image sensor according embodiments.

Referring to FIG. 4, the image sensor according to embodiments may include semiconductor substrate 30, first interlayer dielectric 14, and a plurality of light shield layers 16. The image sensor may further include second interlayer dielectric 18, passivation layer 41, and third interlayer dielectric 24. The image sensor may further include planarization layer 26 and a plurality of microlenses 28. A plurality of transistors, a plurality of photodiodes 12, and a plurality of field insulating layers 10 may be formed on semiconductor substrate 30.

First interlayer dielectric 14 may be formed on a surface (for example, the entire surface) of semiconductor substrate 30 including the plurality of transistors, the plurality of photodiodes 12, and the plurality of field insulating layers 10. The plurality of light shield layers 16 may be formed on first interlayer dielectric 14 to substantially overlap with each field insulating layer 10. Second interlayer dielectric 18 may be formed on a surface (for example, the entire surface) of substrate 30 including light shield layers 16.

Passivation layer 41 may be formed on a surface (for example, the entire surface) of substrate 30 including second interlayer dielectric 18. Third interlayer dielectric 24 may be formed at an upper portion of passivation layer 41, and may include color filter layer 22.

Planarization layer 26 may be formed on a surface (for example, the entire surface) of substrate 30 and may planarize color filter layer 22. The plurality of microlenses 28 may be formed on planarization layer 26 and may overlap with color filter layer 22.

According to embodiments, passivation layer 41 may include first insulating layer 41a, for example made of TEOS material, and second insulating layer 41b, for example made of nitride material.

Each of light shield layers 16 may be disposed to shield field insulating layer 10 and may prevent light from being irradiated to regions other than a formation region of photodiode 12 of substrate 30.

Color filter layer 22 may include red color filter 22a, green color filter 22b, and blue color filter 22c. A photoresist dyed by a color capable of absorbing light of a specific wavelength may be used as material of red, green, and blue color filters 22a, 22b, and 22c. Color filter 22d may be a red, green, or blue filter, or may be another filter.

A polymer system resin may be used as material of microlens 28.

First, second, and third interlayer insulating layers 14, 18, and 24 may be made of transparent insulation materials. In general, first, second, and third interlayer insulating layers 14, 18, and 24 may be achieved by a silicon oxide layer.

The following is a description of a method for manufacturing an image sensor according to embodiments.

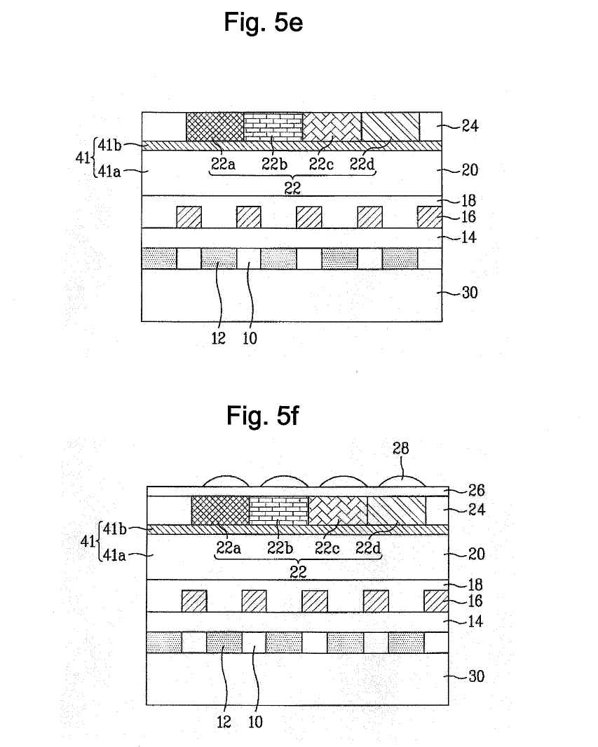

FIGS. 5A through 5F are example cross-sectional diagrams to illustrate a method for manufacturing an image sensor according to embodiments.

Referring to FIG. 5A, a transistor may be formed at each pixel of semiconductor substrate 30. Field insulating layer 10 may be formed for electric insulations between respective pixels. At least one photodiode 12 may be formed between field insulating layers 10.

Referring to FIG. 5B, first interlayer dielectric 14 may be deposited on a surface (for example, the entire surface) of substrate 30 including the transistor, field insulating layers 10, and photodiodes 12.

A plurality of light shield layers 16 may be deposited on first interlayer dielectric 14. In embodiments, light shield layers 16 may be formed on first interlayer dielectric 14 to substantially overlap with respective field insulating layers 10.

Referring to FIG. 5C, second insulating layer 18 may be deposited on field insulating layers 10.

Referring to FIG. 5D, first insulating layer 41a, that may be made of TEOS material, may be deposited on second interlayer dielectric 18. According to embodiments, first insulating layer 41a may be deposited on second interlayer dielectric 18 by an HDP CVD method. According to embodiments, first insulating layer 41a may be deposited on second interlayer dielectric 18 by a PECV method.

Second insulating layer 41b, that may be made of nitride material, may be formed on first insulating layer 41a.

Accordingly, passivation layer 41 may be formed on second interlayer dielectric 18. In embodiments, passivation layer 41 may include first insulating layer 41a and second insulating layer 41b. Passivation layer 41 may protect a device formed on the substrate, for example from scratches or moisture.

Referring to FIG. 5E, photoresist 22 dyed by red, green, and blue colors may be coated and developed on second insulating layer 41b, and may form red, green, and blue color filters 22a, 22b, and 22c. Color filter 22d may also be formed. Third interlayer dielectric 24 may be planarized and formed at a side of color filter layer 22 including red, green, and blue color filters 22a, 22b, and 22c.

Referring to FIG. 5F, planarization layer 26 for planarization adjustment of a focusing distance may be formed on third interlayer dielectric 24.

A plurality of microlenses 28 may be formed at an upper portion of planarization layer 26 corresponding to red, green, and blue color filters 22a, 22b, and 22c.

The passivation layer, the image sensor using the same, and a method for manufacturing the image sensor may have various advantages.

For example, embodiments may prevent an occurrence of a peeling phenomenon in an insulating layer of nitride material using a passivation layer, which may include an insulating layer of TEOS material and an insulating layer of nitride material.

It will be apparent to those skilled in the art that various modifications and variations may be made to embodiments. Thus, it is intended that embodiments cover modifications and variations thereof within the scope of the appended claims. It is also understood that when a layer is referred to as being “on” or “over” another layer or substrate, it may be directly on the other layer or substrate, or intervening layers may also be present.

What is claimed is:

1. An image sensor comprising:
a semiconductor substrate including a photodiode; and
a passivation layer formed over the semiconductor substrate,
wherein the passivation layer comprises a first insulation layer made of TEOS, and a second insulation layer made of a nitride material and formed over the first insulation layer.

2. The device of claim 1, wherein the semiconductor substrate further comprises a transistor.

3. The device of claim 1, further comprising:
a plurality of photodiodes formed on the semiconductor substrate;
a plurality of insulators formed between respective photodiodes on the substrate; and
a plurality of light shields formed over the photodiodes and insulators.

4. The device of claim 3, wherein the plurality of light shields are substantially aligned over respective insulators, and are configured to prevent light from being irradiated onto portions of the substrate other than the photodiodes.

5. The device of claim 4, further comprising a plurality of microlenses formed over the passivation layer, and substantially aligned with respective photodiodes.

6. The device of claim 5, further comprising a plurality of color filters formed between the plurality of microlenses and the passivation layer, each of the plurality of color filters aligned with a corresponding one of the plurality of microlenses.

7. An image sensor comprising:
a substrate including a plurality of photodiodes and transistors;
a passivation layer formed over a surface of the semiconductor substrate and configured to protect the photodiodes and transistors of the substrate;
a color filter layer formed over the passivation layer; and
a plurality of microlenses formed over the color filter layer,
wherein the passivation layer comprises
a first insulation layer made of TEOS; and
a second insulation layer made of a nitride material and formed on the first insulation layer.

8. The image sensor of claim 7, further comprising an interlayer dielectric formed between the substrate and the passivation layer, and comprising at least one layer.

9. The image sensor of claim 8, further comprising a plurality of light shield layers in the interlayer dielectric configured to prevent light from being irradiated to portions other than a formation region of the photodiodes of the substrate.

10. The image sensor of claim 7, further comprising a planarization layer formed between the color filter layer and the microlenses to planarize the color filter layer.

11. A method, comprising:
forming a plurality of photodiodes on a substrate;
forming a first insulating layer of TEOS over the plurality of photodiodes;
forming a second insulating layer of nitride material over the first insulating layer; and
forming a plurality of microlenses over the second insulating layer, each of the plurality of microlenses substantially aligned with a photodiode.

12. The method of claim 11, further comprising forming a color filter layer over the second insulating layer, wherein the plurality of microlenses is formed over the color filter layer.

13. The method of claim 11, further comprising forming an interlayer dielectric formed between the substrate and the first insulating layer, the interlayer dielectric comprising at least one layer.

14. The method of claim 11, further comprising forming a plurality of light shield layers in the interlayer dielectric.

15. The method of claim 14, wherein each of the plurality of light shield layers is aligned over corresponding areas between each of the plurality of photodiodes.

16. The method of claim 11, further comprising forming a planarization layer between the color filter layer and the microlenses.

17. The method of claim 11, wherein the second insulating layer is formed by one of an HDP CVD method and a PECV method.
